(19) United States
(12) Patent Application Publication
(10) Pub. No.: US 2026/0092394 A1
(43) Pub. Date: Apr. 2, 2026

(54) METHOD FOR MANUFACTURING GROUP III NITRIDE SEMICONDUCTOR

(71) Applicants: TOYODA GOSEI CO., LTD., Kiyosu-shi (JP); The University of Osaka, Osaka (JP)

(72) Inventors: Taku FUJIMORI, Kiyosu-shi (JP); Miki MORIYAMA, Kiyosu-shi (JP); Seiji NAGAI, Kiyosu-shi (JP); Yusuke MORI, Osaka (JP); Masayuki IMANISHI, Osaka (JP); Shigeyoshi USAMI, Osaka (JP)

(21) Appl. No.: 19/342,180

(22) Filed: Sep. 26, 2025

(30) Foreign Application Priority Data
Oct. 2, 2024 (JP) 2024-173451

(51) Int. Cl. C30B 19/02; C30B 19/06; C30B 29/40

(52) U.S. Cl. CPC C30B 19/02; C30B 19/067; C30B 29/406

(57) ABSTRACT

A method for manufacturing a group III nitride semiconductor includes a growing step of growing the group III nitride semiconductor on a seed substrate by supplying a gas containing nitrogen to a mixed melt containing a group III metal and a flux. The seed substrate has a substrate and a plurality of seed crystals provided on the substrate and composed of the group III nitride semiconductor. In the method, the growing step includes a generation step of generating an initial nucleus composed of the group III nitride semiconductor on each seed crystal; and a growth step of growing the initial nucleus after the generation step. In the generation step, the mixed melt contains calcium.

### CROSS-REFERENCE

This application claims priority to Japanese Patent Application No. 2024-173451 filed on Oct. 2, 2024, the contents of which are fully incorporated herein by reference.

### TECHNICAL FIELD

The present disclosure relates to a method for manufacturing a group III nitride semiconductor.

### BACKGROUND ART

As a method for manufacturing gallium nitride (GaN), a Na flux method is known. In the Na flux method, nitrogen is dissolved in a mixed melt of gallium (Ga) and sodium (Na) to thereby grow GaN in a liquid phase. In general, the Na flux method grows GaN on a seed substrate by placing the seed substrate in the mixed melt.

A method, in which a seed substrate having a plurality of seed crystals provided thereon is used to generate initial nuclei respectively from the seed crystals and grow the initial nuclei to coalesce, is also known. In this case, if there are variations in the size and shape of the initial nucleus, defects or cracks may occur in the GaN crystal grown on the seed substrate.

In order to reduce variation in size of the initial nuclei, it is considered to improve the generation rate of initial nuclei. According to Patent Document 1, the supersaturation of nitrogen in the mixed melt can be improved by setting the temperature in the generation step at 870° C. or lower, which results in a nucleation rate of 100%.

### SUMMARY

However, JP-A-2020-132464 does not consider the size of seed crystals. The study of the present inventors has clarified that the size of the seed crystal significantly affects the nucleation rate. In particular, it was found that the smaller the seed crystal, the lower the nucleation rate. As a result, it was found that the nucleation rate may not reach 100% even if the method of JP-A-2020-132464 is used.

The present disclosure has been made in view of the background above and aims to provide a method for manufacturing a group III nitride semiconductor, which can improve a nucleation rate.

One aspect of this disclosure is a method for manufacturing a group III nitride semiconductor, the method comprising:
a growing step of growing the group III nitride semiconductor on a seed substrate by supplying a gas containing nitrogen to a mixed melt containing a group III metal and a flux, the seed substrate having a substrate and a plurality of seed crystals provided on the substrate and composed of the group III nitride semiconductor, wherein
the growing step includes:
   a generation step of generating an initial nucleus composed of the group III nitride semiconductor on each seed crystal; and
   a growth step of growing the initial nucleus after the generation step, and in the generation step, the mixed melt contains calcium.

In the above-mentioned aspect, a mixed melt 101 contains calcium in a generation step. This reduces the driving force for crystal growth, improves the generation rate of the initial nuclei from the seed crystals, and uniforms the timing of generation of the initial nuclei. As a result, the shape and size of the initial nuclei are uniformed.

As described above, according to the above-mentioned aspect, a method for manufacturing a group III nitride semiconductor, which makes it possible to improve the nucleation rate, can be provided.

### BRIEF DESCRIPTION OF THE DRAWINGS

FIG. 1 is a flowchart showing a method for manufacturing a group III nitride semiconductor in Embodiment 1.

FIG. 2 is a cross-sectional view of a seed substrate, of which the cross-section is perpendicular to a principal surface of a substrate.

FIG. 3 is a plan view of the seed substrate viewed from above.

FIG. 4 is a cross-sectional view showing a configuration of a seed crystal, of which the cross-section is perpendicular to the principal surface of the substrate.

FIG. 5 is a plan view of the seed substrate viewed from above.

FIG. 6 is a cross-sectional view of the seed substrate in a growth step, of which the cross-section is perpendicular to a principal surface of the substrate.

FIG. 7 is a cross-sectional view of the seed substrate in a planarization step, of which the cross-section is perpendicular to a principal surface of the substrate.

FIG. 8 is a cross-sectional view of the seed substrate in a thickening step, of which the cross-section is perpendicular to a principal surface of the substrate.

FIG. 9 is a schematic view illustrating a FFC method in the planarization step.

FIG. 10 is an SEM image of initial nuclei obliquely viewed from above.

A method for manufacturing a group III nitride semiconductor is a method comprising a growing step of growing the group III nitride semiconductor on a seed substrate by supplying a gas containing nitrogen to a mixed melt containing a group III metal and a flux. The seed substrate has a substrate and a plurality of seed crystals provided on the substrate and composed of the group III nitride semiconductor. The growing step includes a generation step of generating an initial nucleus composed of the group III nitride semiconductor on each seed crystal; and a growth step of growing the initial nucleus after the generation step, and in the generation step, the mixed melt contains calcium.

In the method for manufacturing a group III nitride semiconductor, in the growth step, a calcium concentration of the mixed melt may be less than 0.001 mol %. Variations in the shape and size of the initial nucleus can be more effectively curtailed.

In the method for manufacturing a group III nitride semiconductor, the mixed melt may be held in a crucible, and the crucible may be made of alumina containing calcium to allow the mixed melt to contain calcium in the generation step. Calcium can be simply added to the mixed melt.

In the method for manufacturing a group III nitride semiconductor, a calcium concentration of the mixed melt in the generation step may be 0.001 mol % or more and 0.01 mol % or less. Variations in the shape and size of the initial nucleus can be more effectively curtailed.

In the method for manufacturing a group III nitride semiconductor, the growing step may further comprise a planarization step of forming a planarized crystal surface by filling a gap between initial nuclei adjacent to each other with a buried layer composed of the group III nitride semiconductor after the growth step; and a thickening step of forming a planar layer composed of the group III nitride semiconductor on the planarized crystal surface after the planarization step. In the thickening step, the mixed melt may contain calcium. The crystallinity of the planar layer can be improved.

In the method for manufacturing a group III nitride semiconductor, the calcium concentration of the mixed melt in the thickening step may be set higher than that in the generation step. The crystallinity of the planar layer can be further improved.

In the method for manufacturing a group III nitride semiconductor, a diameter of the seed crystal may be 150 μm or less. Even when the size of the seed crystal is small, variations in the shape and size of the initial nucleus can be more effectively curtailed.

### EMBODIMENT 1

### 1. Outline of Flux Method

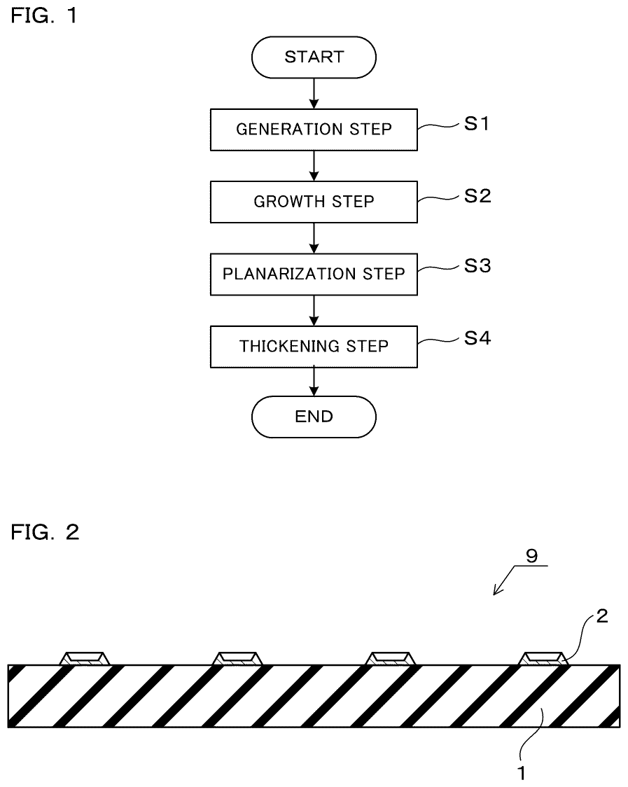

FIG. 1 is a flowchart showing a method of manufacturing a group III nitride semiconductor in Embodiment 1. In the method for manufacturing a group III nitride semiconductor in Embodiment 1, the group III nitride semiconductor is grown by a flux method. The flux method is a method for growing a group III nitride semiconductor epitaxially in the liquid phase by dissolving a mixed melt that contains an alkali metal that acts as a flux and a III group metal as a raw material while supplying a gas containing nitrogen to the mixed melt.

The III group metal as a raw material includes at least one of gallium (Ga), aluminum (Al), and indium (In). A group III nitride semiconductor to be grown can be controlled in composition depending on the ratio of these metals. For example, GaN, AlN, InN, AlGaN, InGaN, AlGaInN, etc. can be grown. This disclosure is particularly suitable for growing GaN.

As the alkali metal acting as a flux, sodium (Na) is usually used. However, potassium (K) or a mixture of Na and K can also be used. In addition, Lithium (Li) and alkaline earth metals can be mixed therein.

Calcium (Ca) is added to a mixed melt according to the manufacturing stage as described below.

Carbon (C) may be added into the mixed melt. Addition of C makes it possible to facilitate the growth of the crystal. In addition, any dopants other than carbon may be added to the mixed melt for the purpose of controlling the physical properties such as conductivity and magnetism of the group III nitride semiconductor to be grown, promoting crystal growth, preventing the growth of polycrystal, and controlling the growth direction.

The gas containing nitrogen may be a gas of nitrogen molecules or a gas of a compound containing nitrogen such as ammonia as a constituent element, and may also be a mixture of these gases or a mixture of the gas containing nitrogen and any inert gas such as a rare gas.

### 2. Structure of Seed Substrate

In Embodiment 1, a seed substrate 9 is placed in the mixed melt to grow a group III nitride semiconductor on the seed substrate 9. Although the seed substrate 9 may be placed in the mixed melt before heated and pressurized, it is preferably put into the mixed melt after heated and pressurized until the growth temperature and growth pressure are reached. This can prevent a seed crystal 2 on the seed substrate 9 from melting back.

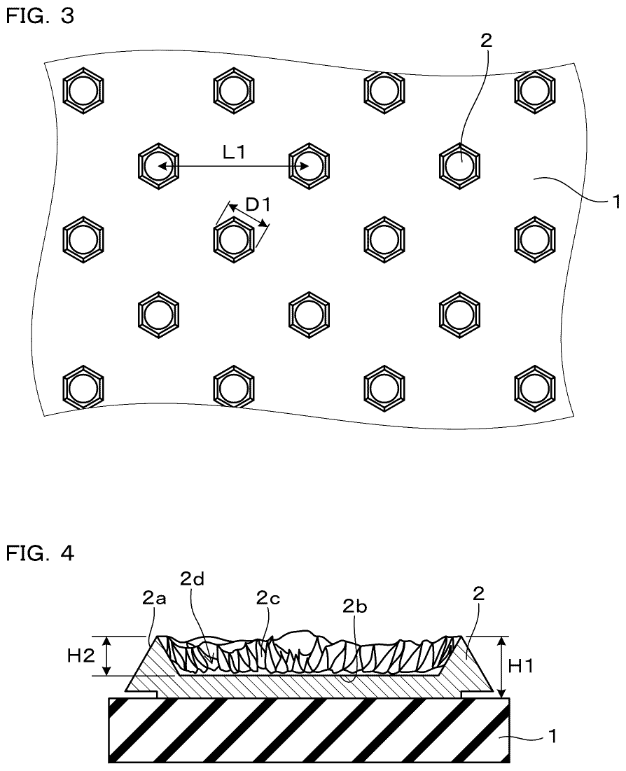

An MPS (multipoint seed) substrate is used for the seed substrate 9. The MPS substrate is a substrate with a plurality of dot-shaped seed crystals 2 arranged periodically on the substrate 1. FIG. 2 is a cross-sectional view of the seed substrate 9, of which the cross-section is perpendicular to a principal surface of the substrate. FIG. 3 is a plan view of the seed substrate 9 viewed from above.

The substrate 1 can be made of a group III nitride semiconductor, sapphire, aluminum oxynitride, SiC, Si, spinel, ZnO, gallium oxide, etc. In the case of a sapphire substrate, for example, the principal surface is c-plane or a-plane.

On the substrate 1, a plurality of the seed crystals 2 are provided via a buffer layer (not shown). The seed crystals 2 are arranged in a triangular lattice pattern. A buffer layer and the seed crystals 2 are made of a group III nitride semiconductor having any composition such as GaN, AlGaN, and AlN. An appropriate material is selected for the buffer layer depending on the material of the seed crystals 2. For example, in the case where the seed crystals 2 are made of GaN, GaN is preferably selected for the buffer layer. The material for the seed crystal 2 usually has the same composition as a group III nitride semiconductor intended to grow by the flux method. Although the seed crystals 2 may be grown using any method, such as MOCVD, HVPE, or MBE, MOCVD and HVPE are preferable in terms of crystallinity and growth time.

The arrangement of the seed crystals 2 is a regular triangular lattice pattern as shown in FIG. 2. The arrangement is not limited to a regular triangular lattice pattern and any periodic arrangement is possible. A pattern with high symmetry, such as a square lattice pattern or a regular triangular lattice pattern is preferable. Such a configuration makes it possible to uniformly combine a group III nitride semiconductors grown from various types of the seed crystal 2 to thereby grow a group III nitride semiconductor with fewer dislocations and warping. In the case of the regular triangular lattice pattern, the direction of the arranging is preferably aligned with the a-axis or m-axis of the seed crystal 2. Here, alignment does not mean a perfect match, and an angular deviation of around 10 degrees with respect to the a-axis or m-axis falls within a tolerance range. The angular deviation with respect to the a-axis or m-axis is preferably less than 1 degree.

The distance L1 between the centers of the seed crystals 2 adjacent to each other is preferably 100 to 2000 μm. This range makes it possible to grow a group III nitride semiconductor with fewer dislocations and warping. The range of the distance L1 is more preferably 200 to 1500 μm, and even more preferably 300 to 1000 μm.

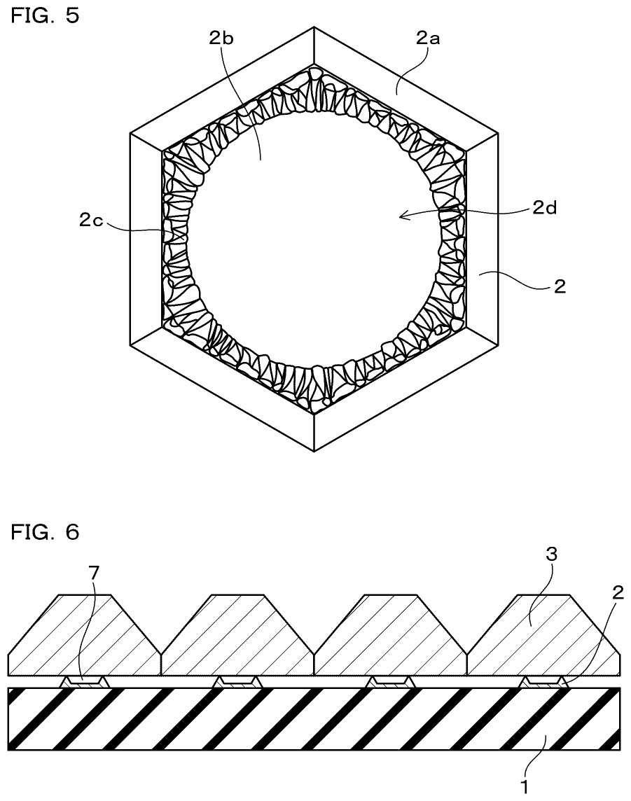

Next, the shape of the seed crystal 2 will be described in detail. FIG. 4 is a cross-sectional view showing a configuration of the seed crystal 2, of which the cross-section is perpendicular to the principal surface of the substrate. FIG. 5 is a plan view showing the configuration of the seed crystal. 2. As shown in FIGS. 4 and 5, the seed crystal 2 has a shape including a disk portion shaped in a form of a circular disk and a truncated regular hexagonal pyramid portion located on the disk portion in contact therewith, shaped in a form of a truncated regular hexagonal pyramid and provided with a recess 2d at its center.

As described below, the seed crystal 2 is formed by selective growth using a mask with an opening, and through which the crystal is grown laterally. The opening of the mask is shaped in a circle in a plan view. Therefore, after the mask is removed, the opening of the mask patterns the substrate in a form of a circular disk. The patterned part corresponds to the disk portion.

The disk portion has the same shape as the opening of the mask for selectively growing the seed crystal 2. Therefore, the thickness of the disk is approximately equal to the thickness of the mask. The diameter of the disk portion is approximately equal to the diameter of the mask opening. A diameter D1 of the truncated regular hexagonal pyramid portion is larger than the diameter of the disk portion. The shape of the disk portion is a circle in a plan view, and thus the stress caused when the substrate 1 is separated after group III nitride semiconductors have been grown using the flux method can be dispersed to thereby curtail occurrence of any cracks in the grown crystal.

Although the shape of the disk portion in a plan view can be changed to a regular hexagon or otherwise by changing the shape of the opening of the mask, a circular form is preferred as it disperses stress as described above.

The bottom surface of the truncated regular hexagonal pyramid portion of the seed crystal has a shape of a regular hexagon. In particular, a regular hexagon with each side aligned with the m-plane of the seed crystal 2 (with each side aligned with the a-axis direction) is preferred because a group III nitride semiconductor is hexagonal, and a regular hexagon allows a group III nitride semiconductor grown from the truncated regular hexagonal pyramid portion of each seed crystal 2 to coalesce uniformly. However, it is not necessary for each side of the regular hexagon to be perfectly aligned with the a-axis, and an angular misalignment of about 10 degrees with respect to the a-axis is acceptable. Preferably, the angular misalignment with respect to the a-axis is 1 degree or less.

Each of the six outer peripheral surfaces 2a of the truncated regular hexagonal pyramid portion of the seed crystal 2 is the (10-11) plane of a group III nitride semiconductor. The (10-11) plane is stable in the mixed melt in the Na-flux method. Therefore, the group III nitride semiconductor grows from the outer peripheral surface 2a of the truncated regular hexagonal pyramid portion of the seed crystal 2 while maintaining the (10-11) plane(s). As a result, the shape of each initial nucleus 3 can be uniformly shaped. The surface of the outer peripheral surface 2a need not be entirely a (10-11) surface, but at least 95% of the entire outer peripheral surface is preferably a (10-11) surface. It is noted that the (10-11) plane referred to here also includes a plane that forms an angle of −5 to 5 degrees with respect to the (10-11) plane as an error.

The diameter D1 (a diameter of the circumscribed circle in a plan view) of the truncated regular hexagonal pyramid portion of the seed crystal 2 is preferably 10 to 500 μm. In this range, a group III nitride semiconductor with fewer dislocations and warpage can be grown. In addition, the area of the outer peripheral surface 2a of the truncated regular hexagonal pyramid portion of the seed crystal 2 can be made larger to thereby facilitate the growth of an initial nucleus 3 from the outer peripheral surface 2a.

Embodiment 1 is particularly effective when the diameter D1 of the seed crystal 2 is small, for example, 150 μm or less, especially 100 μm or less. Although a smaller diameter of the seed crystal 2 makes it easier to separate a substrate 1 after completion of the growth of group III nitride semiconductors, the rate of nucleation from the seed crystal 2 is reduced, which causes variations in the timing of generation of initial nuclei 3. This is because the smaller seed crystal 2 has the less exposed surface on which initial nuclei is easily generated. Therefore, when the diameter D1 of each seed crystal 2 is small, it was difficult to align the shape and size of the initial nuclei 3. However, according to Embodiment 1 mentioned below, the rate of nucleation from the seed crystal 2 can be improved and the timing of generation of initial nuclei 3 can be aligned even when the diameter D1 of each seed crystal 2 is small.

Additionally, a height H1 of the seed crystal 2 is preferably 30 μm or more. Within this range, the outer peripheral surface 2a can have a sufficiently wide area, which enables uniform crystal growth from the outer peripheral surface 2a. As a result, the shapes of the initial nuclei 3 growing from the seed crystals 2 can be uniformly shaped. However, if the H1 is excessively high, there is such a problem that it takes much time to form the seed crystals 2. Thus, the H1 is preferably set to t 100 μm or less. More preferably, it is 20 to 60 μm, and even more preferably, 30 to 50 μm.

Furthermore, for the same reasons as above, the height H1 of the seed crystal 2 is preferably 0.01 to 0.6 times the diameter D1 of the seed crystal 2. More preferably, it is 0.1 to 0.35 times, and even more preferably, it is 0.15 to 0.3 times.

A recess 2d is provided at the center of the seed crystal 2. By providing the recess 2d, the initial nucleus 3 grown from the seed crystal 2 does not fill the recess 2d to form a void 7. The void 7 thus formed prevents dislocations in the seed crystal 2 from propagating upward, which enables growth of a high-quality group III nitride semiconductor.

The bottom surface 2b of the recess 2d is flat and corresponds to a (0001) plane (c-plane) of a group III nitride semiconductor. The bottom surface 2b is approximately circular when viewed in plan. It is noted that the bottom surface 2b does not necessarily need to be flat and may have irregularities. Additionally, the shape of the bottom surface 2b does not necessarily need to be circular when viewed in plan.

The side surface 2c of the recess 2d has a lot of irregularities formed thereon and wholly has the same level of inclination as that of the (10-11) plane. By shaping the side surface 2c to have such irregularities, the side surface 2c serves as a starting point for crystal growth of the group III nitride semiconductor to thereby make it easy to fill the upper portion of the seed crystal 2 with the group III nitride semiconductor. It is noted that the side surface 2c may also be a flat surface.

A depth H2 of the recess 2d is preferably 10 to 100 μm. Within this range, it becomes easier to form voids 7, and thus a higher-quality group III nitride semiconductors can be grown. More preferably, the depth H2 is 20 to 60 μm, and even more preferably, 30 to 50 μm. For the same reasons, the depth H2 of the recess 2d is preferably 0.3 to 1.0 times the height H1 of the seed crystal 2, and more preferably 0.6 to 0.8 times.

The diameter of the top surface of the recess 2d falls within the range such that the seed crystal 2 has no upper surface. The side surface 2c of the recess 2d and the outer peripheral surface 2a of the seed crystal 2 are connected at an angle. Therefore, there is no c-plane on the top of the seed crystal 2. c-plane may be etched in the mixed melt in the Na-flux method, which is a factor of causing variation in the shape of each initial nucleus 3. In addition, dislocations in the seed crystal 2 may be propagated upward by crystal growth from the c-plane. Therefore, if the top of the crystal is shaped to have no c-plane, variation in the shape of each initial nucleus 3 can be curtailed, and dislocation in the seed crystal 2 can be prevented from propagating upward.

### 3. Method of Preparing Seed Substrate

The seed substrate 9 can be prepared, for example, as follows. First, a mask with a plurality of openings is formed on the substrate 1. The openings are arranged in an equilateral triangular lattice pattern. The shape of each opening is a circle. Although shapes other than a circle, such as regular hexagons, are also acceptable, a circle is preferable as used in the embodiment in order to form a disc portion and curtail cracking caused when the substrate is separated. The material of the mask can be any material that can prevent a group III nitride semiconductor from growing on the mask, such as SiO₂.

Next, a buffer layer (not shown) and the seed crystal 2 are selectively grown on the substrate exposed to the opening in sequence by MOCVD, HVPE, or other methods. Next, the mask is removed by wet etching with hydrofluoric acid or the like. The seed substrate 9 can be prepared as described above.

Here, by appropriately controlling the growth conditions when selectively growing the seed crystal 2 through the opening of the mask, facet growth of a group III nitride semiconductors is made possible, so that the seed crystal 2 can be shaped as shown in FIG. 3 and FIG. 4. For example, the growth temperature may be 1120 to 1145° C. and the V/III ratio may be 970 to 1020. The seed crystals 2 can be uniformly shaped because the selective growth determines the shape of each seed crystal 2.

### 4. Method of Manufacturing Group III Nitride Semiconductor

Next, the method of manufacturing a group III nitride semiconductor in Embodiment 1 will be explained with reference to the drawings. As shown in FIG. 1, the manufacturing method of a group III nitride semiconductor in Embodiment 1 includes a growing step of growing the group III nitride semiconductor on the seed substrate 9 by supplying a gas containing nitrogen to the mixed melt containing the group III metal and the flux, the seed substrate 9 having the substrate 1 and the plurality of seed crystals 2 provided on the substrate 1 and composed of the group III nitride semiconductor. The growing step includes a generation step S1, a growth step S2, a planarization step S3, and a thickening step S4.

First, the generation step S1 is performed. In the generation step S1, the furnace atmosphere is replaced with an inert gas, the furnace is heated, and then vacuumed to sufficiently reduce outgas components in the furnace, such as oxygen.

Next, a predetermined amount of an alkali metal and a group III metal are weighed in a glove box in which the atmosphere, such as oxygen and dew point, is controlled. The weighed predetermined amount of the alkali metal and the group III metal are then fed into a crucible 100. If necessary, additive elements such as carbon may be fed.

Next, the crucible 100 in which the raw materials are set and the seed substrate 9 are placed in the reaction vessel and evacuated, and then a gas containing nitrogen is supplied to the reaction vessel. Once the pressure in the reaction vessel reaches a crystal growth pressure, the furnace is heated to a crystal growth temperature. The crystal growth temperature is, for example, 700° C. or higher and 1000° C. or lower, and the crystal growth pressure is, for example, 2 MPa or higher and 10 MPa or lower. In the process of raising the temperature, the solid alkali metal and solid group III metal in the crucible 100 melt and turn into liquid, forming a mixed melt 101. In this stage, the seed substrate 9 is not yet put into the mixed melt 101.

Here, the mixed melt 101 is prepared to contain Ca. Ca can be added to the mixed melt 101 by, for example, the following method.

First, the crucible 100 is made of a material containing Ca. The crucible 100 allows Ca to dissolve into the mixed melt 101, so that the mixed melt can contain Ca. For example, it is preferred to use a crucible 100 made of alumina containing 0.05-0.5 mol % Ca. The crucible 100 containing Ca can be formed by casting molding using a plaster mold.

Second, Ca is added to Na and Ga in advance. When Na and Ga melt by heating to form the mixed melt 101, Ca also melts into the mixed melt 101, thus the mixed melt 101 can contain Ca.

Third, when alkali metals and group III metals are fed into the crucible 100, Ca is also fed. When the Na and Ga melt by heating to form the mixed melt 101, the Ca contained in the Na and Ga also melts into the mixed melt 101, thus the mixed melt 101 can contain Ca.

When the temperature and pressure inside the reaction vessel reach the crystal growth temperature and the crystal growth pressure, and the nitrogen dissolved in the mixed melt 101 reaches supersaturation, the seed substrate 9 is put into the mixed melt 101 in the crucible 100. Thus, crystals of the group III nitride semiconductor (initial nuclei 3) are grown respectively from the crystals 2 of the seed substrate 9.

Here, Ca is added to the mixed melt 101. This reduces the driving force for crystal growth and makes it easier to generate the initial nuclei 3 from the seed crystals 2. Therefore, the timing of the generation of the initial nuclei 3 from the seed crystals 2 is more likely to be aligned. And alignment of the timing of the generation of the initial nuclei 3 can curtail the variation in the shape and size of the initial nuclei 3. As a result, defects and cracks in the seed substrate 9 can be curtailed.

The Ca concentration in the mixed melt 101 is, for example, 0.001 to 0.1 mol %. By setting the Ca concentration to 0.001 mol % or higher, the generation timing of the initial nuclei 3 from the seed crystals 2 can be more effectively aligned. By setting the Ca concentration to 0.1 mol % or less, generation of miscellaneous crystals can be curtailed.

Next, the growth step is performed. In the growth step S2, the growth temperature and pressure in the generation step S1 are maintained to grow the initial nucleus 3 generated in each seed crystal 2 in the generation step S1. The initial nucleus 3 grows in a form of a truncated regular hexagonal pyramid or a regular hexagonal pyramid. Growth of the initial nuclei 3 continues until the initial nuclei 3 adjacent to each other begin to coalesce with each other (see FIG. 6(b)). A gap remains between the initial nuclei 3 and the substrate 1.

In the growth step S2, the mixed melt 101 may contain no Ca. This makes it easy to shape the initial nuclei 3 into a truncated regular hexagonal pyramid, and makes it possible to align the shape and size of the initial nuclei 3 more uniformly. Here, “Ca-free” means the concentration is below the detection limit by general elemental analysis methods. Specifically, the concentration is less than 0.001 mol %.

One method to ensure that the mixed melt 101 does not contain Ca is, for example, to once remove the seed substrate 9 from the crucible 100 and replace the crucible with a different one. In this case, a crucible made of a Ca-free material can be used as another crucible. For example, a crucible made of alumina, which contains no Ca, can be used. This crucible can be used to hold the mixed melt 101 that does not contain Ca.

Here, the (10-11) plane, which is the outer peripheral surface 2a of the truncated regular hexagonal pyramid portion of the seed crystal 2, is stable in the mixed melt 101 without being etched. In addition, the height H1 of the seed crystal 2 is 30 μm or more, and the outer peripheral surface 2a is sufficiently large in area. Therefore, the initial nucleus 3 grows from the outer peripheral surface 2a while maintaining the (10-11) plane. Because the seed crystals 2 are uniformly shaped, the timings of generating the initial nuclei 3 respectively from the seed crystals 2 are uniform, and the initial nuclei 3 uniformly grow from the seed crystal 2 while maintaining the (10-11) plane, variation in the shape of each initial nucleus 3 can be curtailed and the initial nuclei 3 can be uniformly shaped.

Because the recess 2d is formed in the center of the seed crystal 2, the initial nucleus 3 does not fill the recess 2d completely to form a void 7. The void 7 keeps in the mixed melt 101. Because the void 7 is formed at the upper part of the seed crystal 2, dislocations in the seed crystal 2 are prevented from being succeeded upward.

Furthermore, by setting the diameter of the recess 2d large, the seed crystal 2 is formed into a shape that has no upper surface (c-plane). The c-plane may be etched in the mixed melt 101 and is an unstable surface. Because crystal growth from such an unstable surface does not occur, variation in the shape of the initial nucleus 3 can be further curtailed. Additionally, because crystal growth from the c-plane does not occur, the transfer of dislocations from the seed crystal 2 to the upper part can be further curtailed.

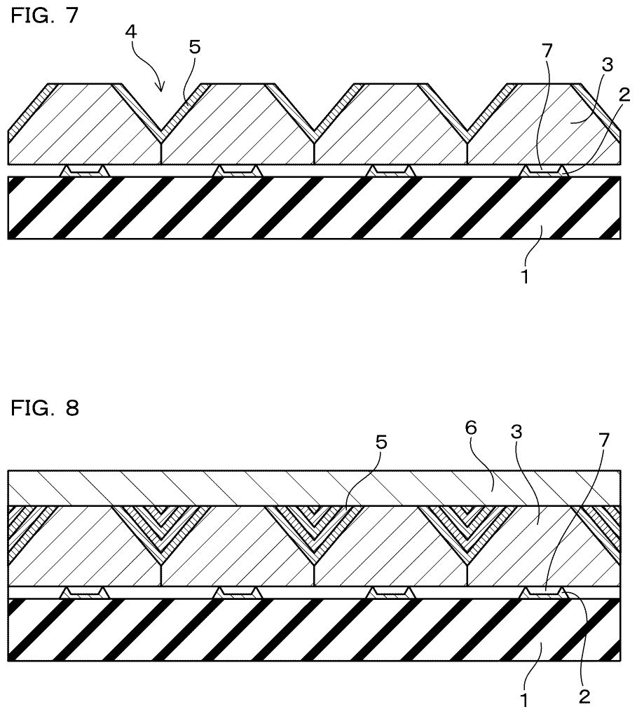

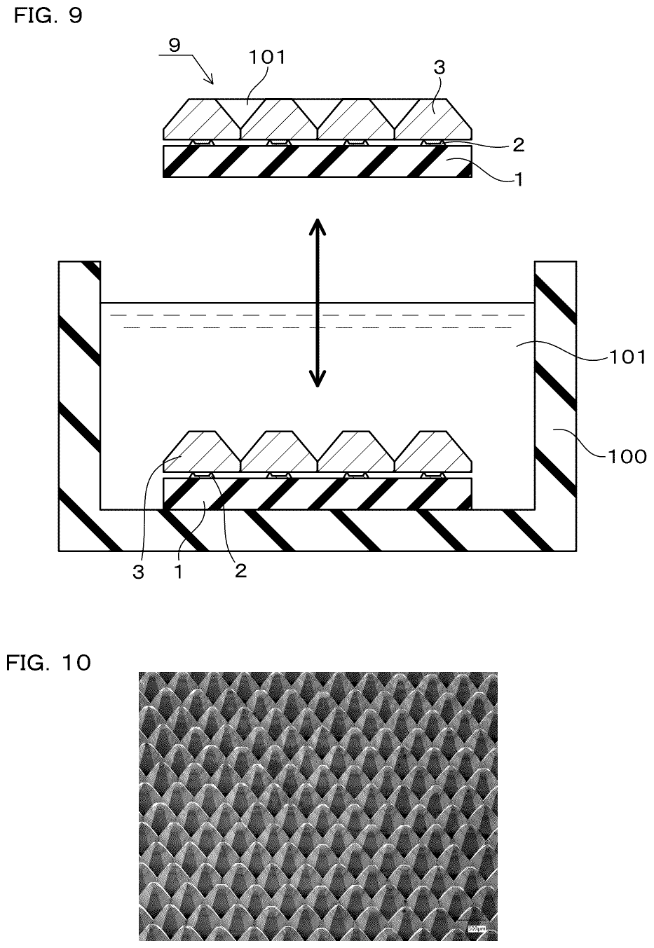

Next, the planarization step S3 is performed. Once the initial nuclei 3 adjacent to each other begin to coalesce with each other, the growth step S2 shifts to the planarization step S3. In the planarization step S3, the crystal is grown using the FFC (flux film coating) method. The FFC method involves repeatedly removing the seed substrate 9 from the mixed melt 101 and then reintroducing it into the mixed melt 101 at predetermined intervals (see FIG. 9). At the stage where the adjacent initial nuclei 3 begin to coalesce, the depression 4 is formed on the coalescent surfaces. When the seed substrate 9 is removed from the mixed melt 101, the mixed melt 101 accumulates in the depressions 4 between the adjacent initial nuclei 3. This allows a buried layer 5 to grow along the depressions 4 (see FIG. 7).

Here, because the mixed melt 101 accumulated in the depression 4 is thin in thickness, nitrogen tends to supersaturate. Thus, the crystal growth rate can be accelerated. However, because the amount of the accumulated mixed melt 101 is small, the amount of the group III metal is also low, so that the crystal growth is caused to cease after some time. To address this, the seed substrate 9 is reintroduced into the mixed melt 101, and the substrate is removed from the mixed melt 101 to thereby intermittently supply the mixed melt 101 containing the group III metal to the depression 4. The FFC method is continued until the depression 4 is filled by growth of the buried layer 5. This enables the growth of crystals with a flat c-plane.

Note that it is not necessary to form the buried layer 5 by the FFC method, however, it is preferable to use the FFC method to further improve the crystal planarity and reduce warpage more. In the planarization step S3, the mixed melt 101 may or may not contain Ca.

Next, the thickening step S4 is performed. When the depression 4 is filled to form a planarized crystal surface, the planarization step S3 shifts to the thickening step S4. In the thickening step S4, the seed substrate 9 is put into the mixed melt 101 again to grow the flat layer 6 and thicken the same on the planarized crystal surface. The flat layer 6 is made of a group III nitride semiconductor with a flat surface. Because the shape of each initial nucleus 3 is uniformed, the flat layer 6 can also be formed uniformly in the plane. In addition, because the upward succession of dislocations in the seed crystal 2 is curtailed, the planar layer 6 can be formed so as to have high quality.

It is noted that in the thickening step S4, the mixed melt 101 preferably contain Ca. Because the wettability of the mixed melt 101 is improved, macrostep growth can be curtailed. As a result, the crystallinity of the planar layer 6 can be improved. In this case, the Ca concentration in the thickening step S4 is preferably set to be higher than that in the generation step S1. In this regard, in terms of preventing miscellaneous crystal, the Ca concentration in the thickening step S4 is preferably set to 1 mol % or less.

Once the flat layer 6 has grown to the desired thickness, the temperature is lowered to room temperature and the pressure is also lowered to normal pressure to terminate the growth of the group III nitride semiconductor. Here, the gap between the initial nucleus 3 and the substrate 1 remains unfilled. Therefore, the substrate 1 can be spontaneously separated due to the difference in thermal expansion coefficients during temperature dropping. In particular, when the diameter D1 of the seed crystal 2 is 150 μm or less, the substrate 1 can be peeled off more easily.

As described above, according to the method of manufacturing a group III nitride semiconductor in Embodiment 1, because Ca is added to the mixed melt 101 in the generation step, the nucleation rate of each initial nucleus 3 from each seed crystal 2 can be improved. In addition, the timing of generating each initial nucleus 3 from each seed crystal 2 is uniformed. As a result, the shape and size of the initial nuclei 3 can be uniformed, which makes it possible to prevent defects and cracks in the seed substrate 9

Next, the experimental results on Embodiment 1 will be described.

First, the seed substrate 9 was prepared as follows. A mask made of SiO₂ was formed on the substrate 1 composed of c-plane sapphire by CVD method. The mask had a pattern of openings arranged in an equilateral triangular lattice. The openings are shaped circular. The distance between the centers of adjacent openings was 550 μm, and the diameter of the openings was 175 μm. Next, a buffer layer was formed on the bottom of the openings by the MOCVD method, and the seed crystal 2 composed of GaN was subsequently formed on the buffer layer. The seed crystal 2 was grown at a temperature of 1140° C. with a V/III ratio of 720. The seed substrate 9 was prepared as described above.

Next, a crucible 100 made of alumina containing 0.1 mol % Ca was prepared. Then, seed substrate 9, sodium, and gallium were put into the crucible 100, and heated and pressurized in a nitrogen atmosphere to thereby grow GaN crystals on the seed substrate 9. The growth allowed the initial nuclei 3 to grow from the seed crystals 2 to the extent that the initial nuclei 3 grown from the adjacent seed crystals coalesced.

FIG. 10 is an SEM image of the grown initial nuclei 3. As shown in FIG. 10, it was found that the initial nuclei 3 were uniform in shape and size. This is considered because the mixed melt 101 containing Ca melted out of the crucible 100 during the nucleation stage of the initial nuclei 3 facilitates generation of the initial nuclei 3, and thus the growth timing of the initial nuclei 3 is aligned.

What is claimed is:

1. A method for manufacturing a group III nitride semiconductor, the method comprising:
a growing step of growing the group III nitride semiconductor on a seed substrate by supplying a gas containing nitrogen to a mixed melt containing a group III metal and a flux, the seed substrate having a substrate and a plurality of seed crystals provided on the substrate and composed of the group III nitride semiconductor, wherein
the growing step includes:
a generation step of generating an initial nucleus composed of the group III nitride semiconductor on each seed crystal; and
a growth step of growing the initial nucleus after the generation step, and
in the generation step, the mixed melt contains calcium.

2. The method according to claim 1, wherein in the growth step, a calcium concentration of the mixed melt is less than 0.001 mol %.

3. The method according to claim 1, wherein
the mixed melt is held in a crucible, and
the crucible is made of alumina containing calcium to allow the mixed melt to contain calcium in the generation step.

4. The method according to claim 1, a calcium concentration of the mixed melt in the generation step is 0.001 mol % or more and 0.01 mol % or less.

5. The method according to claim 2, a calcium concentration of the mixed melt in the generation step is 0.001 mol % or more and 0.01 mol % or less.

6. The method according to claim 1, wherein
the growing step further comprises
a planarization step of forming a planarized crystal surface by filling a gap between initial nuclei adjacent to each other with a buried layer composed of the group III nitride semiconductor after the growth step; and
a thickening step of forming a planar layer composed of the group III nitride semiconductor on the planarized crystal surface after the planarization step, and
in the thickening step, the mixed melt contains calcium.

7. The method according to claim 2, wherein
the growing step further comprises
a planarization step of forming a planarized crystal surface by filling a gap between initial nuclei adjacent to each other with a buried layer composed of the group III nitride semiconductor after the growth step; and
a thickening step of forming a planar layer composed of the group III nitride semiconductor on the planarized crystal surface after the planarization step, and
in the thickening step, the mixed melt contains calcium.

8. The method according to claim 6, wherein
the calcium concentration of the mixed melt in the thickening step is higher than that in the generation step.

9. The method according to claim 7, wherein
the calcium concentration of the mixed melt in the thickening step is higher than that in the generation step.

10. The method according to claim 1, wherein a diameter of the seed crystal is 150 μm or less.
